(19) United States
(12) Patent Application Publication
(10) Pub. No.: US 2025/0301632 A1
(43) Pub. Date: Sep. 25, 2025

(54) SEMICONDUCTOR DEVICES

(71) Applicant: Samsung Electronics Co., Ltd., Suwon-si (KR)

(72) Inventors: Taejin Park, Suwon-si (KR); Sungsoo Yim, Suwon-si (KR)

(21) Appl. No.: 19/070,664

(22) Filed: Mar. 5, 2025

(30) Foreign Application Priority Data
Mar. 20, 2024 (KR) 10-2024-0038443

(51) Int. Cl. H10B 12/00

(52) U.S. Cl. CPC H10B 12/33; H10B 12/036; H10B 12/05; H10B 12/50

(57) ABSTRACT

A semiconductor device includes a capacitor on a first substrate, a channel on the capacitor and extending in a vertical direction, a first gate electrode at a side of the channel in a first direction and extending in a second direction, a bit line contacting the channel, a first wiring on the bit line, a first insulating interlayer on the bit line and the first wiring, a bonding layer bonded to the first insulating interlayer, a second substrate bonded to the bonding layer, at least a portion of a transistor on the second substrate, a second insulating interlayer on the second substrate, a second wiring on the second insulating interlayer, an insulation pattern extending through the second substrate, the bonding layer and the first insulating interlayer and contacting the first wiring, and a through via extending through the second insulating interlayer and the insulation pattern and contacting the first and second wirings.

### CROSS-REFERENCE TO RELATED APPLICATION

This application claims priority under 35 U.S.C. § 119 to Korean Patent Application No. 10-2024-0038443 filed on Mar. 20, 2024 in the Korean Intellectual Property Office, the disclosure of which is hereby incorporated by reference in its entirety.

### TECHNICAL FIELD

Example embodiments of the present disclosure relate to a semiconductor device. More particularly, example embodiments of the present disclosure relate to a memory device including a vertical channel.

### DISCUSSION OF RELATED ART

In order to improve an integration degree of a semiconductor device, a memory device including a vertical channel transistor has been developed. For example, a memory cell and a periphery circuit pattern are formed on different substrates and the substrates are bonded with each other. However, as the number of bonding increases, the cost for manufacturing the memory device increases.

### SUMMARY

Example embodiments provide a semiconductor device having improved characteristics.

According to example embodiments, there is provided a semiconductor device. The semiconductor device may include a capacitor on a first substrate, a channel on and electrically connected to the capacitor and extending in a vertical direction perpendicular to an upper surface of the first substrate, a first gate electrode at a side of the channel, the first gate electrode spaced apart from the channel in a first direction parallel to the upper surface of the first substrate and extending in a second direction parallel to the upper surface of the first substrate and crossing the first direction, a bit line in contact with and electrically connected to an end of the channel in the vertical direction and extending in the first direction, a first wiring on the bit line, a first insulating interlayer on the bit line and the first wiring, a bonding layer bonded to an upper surface of the first insulating interlayer, a second substrate bonded to an upper surface of the bonding layer, a transistor at least a portion of which is on the second substrate, a second insulating interlayer on the second substrate and covering the transistor, a second wiring on the second insulating interlayer, an insulation pattern extending through the second substrate, the bonding layer and an upper portion of the first insulating interlayer and contacting an upper surface of the first wiring, and a through via extending through the second insulating interlayer and the insulation pattern and contacting the first and second wirings.

According to example embodiments, there is provided a semiconductor device. The semiconductor device may include a capacitor on a first substrate, a plate electrode covering a lower surface and a sidewall of the capacitor, a channel on and electrically connected to the capacitor and extending in a vertical direction perpendicular to an upper surface of the first substrate, and a first gate electrode at a side of the channel. The side of the channel faces the first gate electrode in a first direction, the first gate electrode extends in a second direction, the first and second directions are parallel to the upper surface of the first substrate, and the second direction crosses the first direction. The semiconductor device may further include a bit line in contact with and electrically connected to an end of the channel in the vertical direction and extending in the first direction, a first wiring on the bit line, a first insulating interlayer covering the bit line and the first wiring, a bonding layer bonded to an upper surface of the first insulating interlayer, a second substrate bonded to an upper surface of the bonding layer, a transistor at least a portion of which is on the second substrate, a second wiring on the second substrate, and an insulation pattern extending through the second substrate, the bonding layer and an upper portion of the first insulating interlayer and contacting an upper surface of the first wiring.

According to example embodiments, there is provided a semiconductor device. The semiconductor device may include a capacitor on a first substrate, a plate electrode covering a lower surface and a sidewall of the capacitor, a channel on and electrically connected to the capacitor and extending in a vertical direction perpendicular to an upper surface of the first substrate, a word line at a first side of the channel, the word line spaced apart from the channel in a first direction parallel to the upper surface of the first substrate and extending in a second direction parallel to the upper surface of the first substrate and crossing the first direction, and a first gate insulation pattern covering an upper surface of the word line and a pair of sidewalls of the word line. The pair of sidewalls of the word line face each other in the first direction. The semiconductor device may further include a back gate electrode at a second side of the channel, the back gate electrode spaced apart from the channel in the first direction and extending in the second direction, and a second gate insulation pattern covering an upper surface of the back gate electrode and a pair of sidewalls of the back gate electrode. The pair of sidewalls of the back gate electrode face each other in the first direction. The semiconductor device may further include a bit line in contact with and electrically connected to an end of the channel in the vertical direction and extending in the first direction, a first wiring on the bit line, a first insulating interlayer covering the bit line and the first wiring, a bonding layer bonded to an upper surface of the first insulating interlayer, a second substrate bonded to an upper surface of the bonding layer, a transistor at least a portion of which is on the second substrate, a second insulating interlayer on the second substrate and covering the transistor, a second wiring on the second insulating interlayer, an insulation pattern extending through the second substrate, the bonding layer and an upper portion of the first insulating interlayer and contacting an upper surface of the first wiring, and a through via extending through the second insulating interlayer and the insulation pattern and contacting the first and second wirings.

According to example embodiments, there is provided a semiconductor device. The semiconductor device may include a channel extending in a vertical direction, a first gate electrode at a side of the channel, the first gate electrode spaced apart from the channel in the a first direction, a first wiring on the first gate electrode and electrically connected to an end of the channel, a first insulating interlayer covering the first wiring, a second substrate in contact with an upper surface of the first insulating interlayer, a transistor at least a portion of which is on the second substrate, a second wiring on the second substrate, an insulation pattern extending through the second substrate and an upper portion of the first insulating interlayer, the insulation pattern contacting an upper surface of the first wiring, and a through via extending through the second insulating interlayer and the insulation pattern and contacting the first and second wirings.

According to example embodiments, there is provided a semiconductor device. The semiconductor device may include a channel extending in a vertical direction, a first gate electrode at a side of the channel and spaced apart from the channel in a first direction, a first wiring on the first gate electrode and electrically connected to an end of the channel, a first insulating interlayer covering the first wiring, a second substrate in contact with an upper surface of the first insulating interlayer, a first transistor at least a portion of which is on the second substrate, a second wiring on the second substrate, an insulation pattern extending through the second substrate and an upper portion of the first insulating interlayer and contacting an upper surface of the first wiring, and a through via extending through the second insulating interlayer and the insulation pattern and contacting the first and second wirings.

In example embodiments, the second substrate may be bonded with the upper surface of the first insulating interlayer, the channel and the first gate electrode may be parts of a second transistor of a memory cell, and the first transistor may be a part of a peripheral circuit.

In the method of manufacturing the semiconductor device in accordance with example embodiments, the number of bonding the substrates on which the memory cells and the peripheral circuit patterns are formed, respectively, may decrease, and thus the cost for manufacturing the semiconductor device may decrease.

### BRIEF DESCRIPTION OF THE DRAWINGS

FIG. 1 is a cross-sectional view illustrating a semiconductor device in accordance with example embodiments.

FIGS. 2 to 12 are plan views and cross-sectional views illustrating a method of manufacturing a semiconductor device in accordance with example embodiments.

FIG. 13 is a cross-sectional view illustrating a semiconductor device in accordance with example embodiments.

FIGS. 14 and 15 are cross-sectional views illustrating a method of manufacturing a semiconductor device.

FIGS. 16 to 20 are cross-sectional views illustrating a method of manufacturing a semiconductor device in accordance with example embodiments.

### DETAILED DESCRIPTION

The above and other aspects and features of a semiconductor device, as well as a method of manufacturing the same in accordance with example embodiments, will become readily understood from detail descriptions that follow, with reference to the accompanying drawings.

It will be understood that, although the terms “first,” “second,” and/or “third” may be used herein to describe various elements, steps, etc. (e.g., materials, layers (films), regions, electrodes, pads, patterns, structures and processes), these elements, steps, etc. should not be limited by the ordinal terms. Unless the context indicates otherwise, these ordinal terms are only used to distinguish one of elements, steps, etc. from another. Thus, for example, a “first” element discussed below in one section of the specification could be termed a “second” element in another section without departing from the teachings of the inventive concepts.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” “perpendicular,” “parallel,” “flat,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Hereinafter, in the specification (and not necessarily in the claims), two directions that are substantially perpendicular to each other among horizontal directions, which are substantially parallel to an upper surface of each of first, second and third substrates, may be referred to as first and second directions D1 and D2, respectively, and a vertical direction substantially perpendicular to the upper surface of each of the first to third substrates may be referred to as a third direction D3. In example embodiments, the first and second directions D1 and D2 may be orthogonal to each other. Each of the first to third directions D1, D2 and D3 may represent not only the orientation depicted in the drawings but also an opposite orientation thereto.

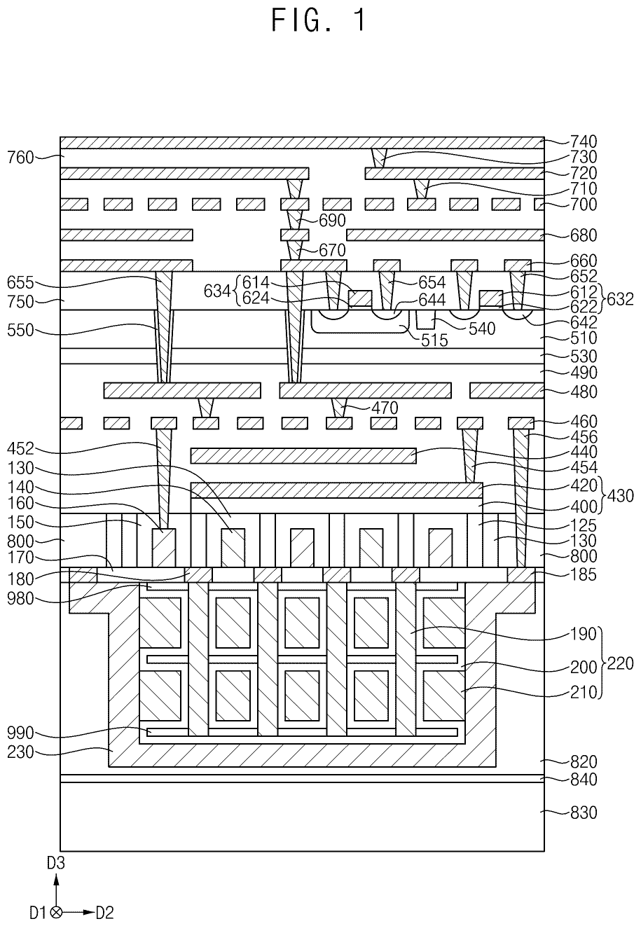

FIG. 1 is a cross-sectional view illustrating a semiconductor device in accordance with example embodiments.

Referring to FIG. 1, the semiconductor device may include memory cells and peripheral circuit patterns on a second substrate 830. For example, the semiconductor device may be a dynamic random access memory (DRAM).

The semiconductor device may have a periphery over cell (POC) structure in which the peripheral circuit patterns are disposed over the memory cells. However, the inventive concept is not limited thereto, and the semiconductor device may also have a cell over periphery (COP) structure by flipping the semiconductor device of FIG. 1.

The semiconductor device may include a capacitor 220, a plate electrode 230, first and second pads 180 and 185, first and second gate electrodes 140 and 160, first and second gate insulation patterns 130 and 150, a channel 125, a bit line structure (which may be a bit line) 430, first and second transistors and a wiring structure.

The semiconductor device may further include first and second bonding layers 840 and 530, first to sixth insulating interlayers 800, 170, 820, 490, 750 and 760 and first insulation patterns 550.

The second substrate 830 may include a semiconductor material, e.g., silicon, or an insulating material, e.g., glass. The first bonding layer 840 may be bonded with an upper surface of the second substrate 830, and may include, e.g., silicon carbonitride, silicon oxide, etc. The third insulating interlayer 820 may be bonded with an upper surface of the first bonding layer 840, and may include an oxide, e.g., silicon oxide or a low-k dielectric material. For example, the first bonding layer 840 may be in contact with the upper surface of the second substrate 830 by using anodic bonding, hydrogen ion bonding (hydrogen wafer bonding), thermal direct bonding (or molecular bonding), or plasma-activated bonding. For example, the third insulating interlayer 820 may be in contact with the upper surface of the first bonding layer 840 by using anodic bonding, hydrogen ion bonding (hydrogen wafer bonding), thermal direct bonding (or molecular bonding), or plasma-activated bonding.

The capacitor 220 and the plate electrode 230 may be disposed in the third insulating interlayer 820, and a lower surface and a sidewall of the plate electrode 230 may be covered by the third insulating interlayer 820. The capacitor 220 may include a first capacitor electrode 190, a dielectric layer 200 and a second capacitor electrode 210.

The first capacitor electrode 190 may extend in the third direction D3, and a plurality of first capacitor electrodes 190 may be spaced apart from each other in each of the first and second directions D1 and D2. In example embodiments, the first capacitor electrode 190 may be arranged in a lattice pattern or a honeycomb pattern in a plan view.

A support layer 990 and an etch stop layer 980 may be disposed on a sidewall of each of the first capacitor electrodes 190. The etch stop layer 980 may be disposed on an uppermost portion of the sidewall of each of the first capacitor electrodes 190, and a plurality of support layers 990 may be spaced apart from each other in the third direction D3 on the sidewall of each of the first capacitor electrodes 190.

The dielectric layer 200 may be disposed on the sidewall of the first capacitor electrode 190, lower and upper surfaces and a sidewall of the support layer 990 and a lower surface and a sidewall of the etch stop layer 980, and the second capacitor electrode 210 may be disposed between ones of the support layers 990 neighboring in the third direction D3 and between an uppermost one of the support layers 990 and the etch stop layer 980. A sidewall of the second capacitor electrode 210 may be covered by the dielectric layer 200.

The plate electrode 230 may surround lower surfaces and sidewalls of the capacitor 220, the support layer 990 and the etch stop layer 980.

Each of the first and second capacitor electrodes 190 and 210 may include, e.g., a metal, a metal nitride, a metal silicide, etc., and the dielectric layer 200 may include a metal oxide. The support layer 990 may include an insulating nitride, e.g., silicon nitride, and the etch stop layer 980 may include an insulating nitride, e.g., silicon boronitride. The plate electrode 230 may include a metal, e.g., tungsten or doped silicon-germanium.

The second insulating interlayer 170 may be disposed on the third insulating interlayer 820. The first and second pads 180 and 185 may extend through the second insulating interlayer 170, and may contact the first capacitor electrode 190 and the plate electrode 230, respectively, to be electrically connected thereto. As the first capacitor electrodes 190 are arranged in the lattice pattern or honeycomb pattern, the first pads 180 may also be arranged in the lattice pattern or honeycomb pattern.

The second insulating interlayer 170 may include an oxide, e.g., silicon oxide or a low-k dielectric material, and each of the first and second pads 180 and 185 may include, e.g., a metal, a metal nitride, a metal silicide, etc.

In example embodiments, the first gate electrode 140 may extend in the first direction D1 on the second insulating interlayer 170, and a plurality of first gate electrodes 140 may be spaced apart from each other in the second direction D2. The second gate electrode 160 may extend in the first direction D1 on the second insulating interlayer 170, and a plurality of second gate electrodes 160 may be spaced apart from each other in the second direction D2. In example embodiments, the first and second gate electrodes 140 and 160 may be alternately and repeatedly arranged in the second direction D2.

In example embodiments, the first gate electrode 140 may have a straight bar shape extending in the first direction D1 in a plan view, while the second gate electrode 160 may include an extension portion straightly extending in the first direction D1 and protrusion portions, each of which may protrude in the second direction D2 from the extension portion, spaced apart from each other in the first direction D1.

Each of the first and second gate electrodes 140 and 160 may include a metal, e.g., tungsten, copper, aluminum, etc.

In example embodiments, the second gate electrode 160 may serve as a word line of the semiconductor device, and the first gate electrode 140 may serve as a back gate electrode of the semiconductor device. The channel 125 and the first and second gate electrode 150 and 160 may be parts of a second transistor of the memory cell.

In example embodiments, the first gate insulation pattern 130 may be disposed on the second insulating interlayer 170 and the first pad 180, and may extend in the first direction D1 and cover an upper surface and a sidewall of the first gate electrode 140. For example, the first gate insulation pattern 130 may cover a pair of sidewalls of the first gate electrode 140, and the pair of sidewalls of the first gate electrode 140 may face away from each other in the second direction D2. The second gate insulation pattern 150 may be disposed on the second insulating interlayer 170 and the first pad 180, and may extend in the first direction D1 and cover an upper surface and a sidewall of the second gate electrode 160. For example, the second gate insulation pattern 150 may cover a pair of sidewalls of the second gate electrode 160, and the pair of sidewalls of the second gate electrode 160 may face away from each other in the second direction D2. A cross-section in the second direction D2 of each of the first and second gate insulation patterns 130 and 150 may have, e.g., a cup shape.

As the first and second gate electrodes 140 and 160 are alternately and repeatedly arranged in the second direction D2, the first and second gate insulation patterns 130 and 150 may also be arranged in the second direction D2.

In example embodiments, each of opposite sidewalls in the second direction D2 of the first gate insulation pattern 130 may have a shape of a straight line extending in the first direction D1 in a plan view, while each of opposite sidewalls in the second direction D2 of the second gate insulation pattern 130 may have a zigzag pattern in a plan view. Each of the first and second gate insulation patterns 130 and 150 may include an oxide, e.g., silicon oxide.

The channel 125 may be disposed on the first pad 180, and a plurality of channels 125 may be spaced apart from each other in the first direction D1 on an outer sidewall in the second direction D2 of the first gate insulation pattern 130. A first sidewall in the second direction D2 of each of the channels 125 may contact the outer sidewall in the second direction D2 of the first gate insulation pattern 130, and a second sidewall in the second direction D2 and opposite sidewalls in the first direction D1 of each of the channels 125 may contact an outer sidewall in the second direction D2 of the second gate insulation pattern 150.

The first gate electrode 140 may be disposed at a side of the channel 125 and may extend in the first direction D1. The side of the channel 125 may face the first gate electrode in the second direction D2. The first gate electrode 140 may be spaced apart from the channel 125 in the second direction D2 such that the first gate insulation pattern 130 is disposed between the first gate electrode 140 and the channel 125.

The second gate electrode 160 may be disposed at another side of the channel 125 and may extend in in the first direction D1. The other side of the channel 125 may face the second gate electrode 160 in the second direction D2. The second gate electrode 160 may be spaced apart from the channel 125 in the second direction D2 such that the second gate insulation pattern 150 is disposed between the second gate electrode 160 and the channel 125.

In example embodiments, the channel 125 may include a semiconductor material, e.g., silicon, germanium, silicon-germanium, etc. Alternatively, the channel 125 may include an oxide semiconductor material, e.g., IGZO.

The first insulating interlayer 800 may be disposed on the second insulating interlayer 170 and the second pad 185, and may contact a sidewall of one of the first gate insulation patterns 130 at each of opposite sides in the second direction D2. The first insulating interlayer 800 may include an oxide, e.g., silicon oxide or a low-k dielectric material.

The bit line structure 430 may extend in the second direction D2 on the channel 125, the first and second gate insulation patterns 130 and 150 and the first insulating interlayer 800, and a plurality of bit line structures 430 may be spaced apart from each other in the first direction D1. Each of the bit line structures 430 may contact upper surfaces of ones of the channels 125 disposed in the second direction D2.

In an example embodiment, each of the bit line structures 430 may include first and second conductive patterns 400 and 420 stacked in the third direction D3, and may include, e.g., doped polysilicon and a metal, respectively.

First to third wirings 440, 460 and 480, first to third contact plugs 452, 454 and 456 and the first via 470 may be disposed on the bit line structure 430, and may be covered by the fourth insulating interlayer 490 on the channel 125, the first and second gate insulation patterns 130 and 150 and the first insulating interlayer 800.

The first to third wirings 440, 460 and 480 may be sequentially stacked in the third direction D3 in order. The first contact plug 452 may extend through a portion of the fourth insulating interlayer 490 and the second gate insulation pattern 150 to contact a lower surface of the second wiring 460 and an upper surface of the second gate electrode 160, the second contact plug 454 may extend through a portion of the fourth insulating interlayer 490 to contact the lower surface of the second wiring 460 and an upper surface of the bit line structure 430, and the third contact plug 456 may extend through a portion of the fourth insulating interlayer 490 and the first insulating interlayer 800 to contact the lower surface of the second wiring 460 and an upper surface of the second pad 185.

Each of the first to third wirings 440, 460 and 480, the first to third contact plugs 452, 454 and 456 and the first via 470 may include, e.g., a metal, a metal nitride, a metal silicide, etc., and the fourth insulating interlayer 490 may include an oxide, e.g., silicon oxide or a low-k dielectric material.

The second bonding layer 530 may be bonded with an upper surface of the fourth insulating interlayer 490, and may include, e.g., silicon carbonitride, silicon oxide, etc. The second bonding layer 530 may be a composite layer including a plurality of sub-layers. Each of the plurality of sub-layers may be formed of insulating material (e.g., silicon carbonitride, silicon oxide, etc.), but the invention is not limited thereto. The second bonding layer 530 may be disposed on a substantially entire portion of the upper surface of the fourth insulating interlayer 490. For example, the second bonding layer 530 may entirely cover the upper surface of the fourth insulating interlayer 490 except for the areas where through vias 655 (described later) and first insulation patterns 550 are formed.

For example, the second bonding layer 530 may be in contact with the upper surface of the fourth insulating interlayer 490 by using anodic bonding, hydrogen ion bonding (hydrogen wafer bonding), thermal direct bonding (or molecular bonding), or plasma-activated bonding.

A third substrate 510 and the peripheral circuit patterns may be disposed on the second bonding layer 530. The peripheral circuit patterns may be circuit patterns for, e.g., a bit line sense amplifier (BLSA), a sub-word line driver (SWD), a column decoder, a common select line (CSL) driver, an input/output (I/O) sense amplifier (SA), a write driver, etc.

The third substrate 510 may include a semiconductor material, e.g., silicon, germanium, silicon-germanium, etc., and may include a well region doped with, e.g., p-type impurities (charge carrier dopants).

An isolation pattern 540 may be formed at an upper portion of the third substrate 510, and the first insulation pattern 550 may extend through the third substrate 510, the second bonding layer 530 and the fourth insulating interlayer 490 to contact an upper surface of the third wiring 480. Each of the isolation pattern 540 and the first insulation pattern 550 may include an oxide, e.g., silicon oxide.

First and second gate structures 632 and 634 may be disposed on the third substrate 510, and second and third impurity regions 642 and 644 may be formed at upper portions of the third substrate 510 adjacent to the first and second gate structures 632 and 634, respectively. In an example embodiment, the second impurity region 642 may include n-type impurities, and the third impurity region 644 may include p-type impurities. A first impurity region 515 doped with n-type impurities may be further formed at a portion of the third substrate 510 under the second gate structure 634, and may surround the third impurity region 644.

The first gate structure 632 may include a third gate insulation pattern 622 and a third gate electrode 612 stacked in the third direction D3, and the second gate structure 634 may include a fourth gate insulation pattern 624 and a fourth gate electrode 614 stacked in the third direction D3.

A plurality of transistors may be provided and at least a portion of each transistor may be formed on the third substrate 510. The plurality of transistors may be parts of the peripheral circuit (e.g., the bit line sense amplifier (BLSA), the sub-word line driver (SWD), the column decoder, the common select line (CSL) driver, the input/output (I/O) sense amplifier (SA), the write driver, etc.). The first gate structure 632 and the second impurity regions 642 may collectively form a first transistor, and the second gate structure 634 and the third impurity regions 644 may collectively form a second transistor. The first transistor may be an NMOS transistor, and the second transistor may be a PMOS transistor. FIG. 1 shows that the first and second transistors, which may be the NMOS and PMOS transistors, respectively, however, the inventive concept is not limited thereto.

Each of the third and fourth gate electrodes 612 and 614 may include a conductive material, e.g., a metal, a metal nitride, a metal silicide, etc., and each of the third and fourth gate insulation patterns 622 and 624 may include an oxide, e.g., silicon oxide.

The fifth and sixth insulating interlayers 750 and 760 may be stacked in the third direction D3 on the third substrate 510. Each of the fifth and sixth insulating interlayers 750 and 760 may include an oxide, e.g., silicon oxide or a low-k dielectric material.

Fourth and fifth contact plugs 652 and 654 may extend through the fifth insulating interlayer 750 to contact upper surfaces of the second and third impurity regions 642 and 644, respectively, and a through via 655 may extend through the fifth insulating interlayer 750 and the first insulation pattern 550 to contact an upper surface of the third wiring 480.

The fourth to eighth wirings 660, 680, 700, 720 and 740 may be sequentially stacked in the third direction D3 in order.

A sixth contact plug 670 may extend through a portion of the sixth insulating interlayer 760 to contact an upper surface of the fourth wiring 660 and a lower surface of the fifth wiring 680, the second via 690 may extend through a portion of the sixth insulating interlayer 760 to contact an upper surface of the fifth wiring 680 and a lower surface of the sixth wiring 700, the third via 710 may contact an upper surface and a lower surface of the seventh wiring 720, and the fourth via 730 may contact an upper surface of the seventh wiring 720 and a lower surface of the eighth wiring 740.

FIG. 1 shows that the fourth to eighth wirings 660, 680, 700, 720 and 740 stacked in the sixth insulating interlayer 760 in the third direction D3, however, the inventive concept is not limited thereto.

Each of the fourth to eighth wirings 660, 680, 700, 720 and 740, the fourth and fifth contact plugs 652 and 654, the through via 655, and the second to fourth vias 690, 710 and 730 may include a conductive material, e.g., a metal, a metal nitride, a metal silicide, etc.

In the semiconductor device, currents may flow in the channel 125 in the third direction D3, which is the vertical direction, between the bit line structure 430 and the first pad 180, and thus the semiconductor device may include a vertical channel transistor (VCT) having a vertical channel.

In some embodiments of the invention, the second bonding layer 530 may not be formed. In this case, the upper surface of the fourth insulating interlayer 490 may be bonded with (e.g., in contact with) overlying parts of the semiconductor device. For example, the upper surface of the fourth insulating interlayer 490 may be bonded with (e.g., in contact with) the third substrate 510.

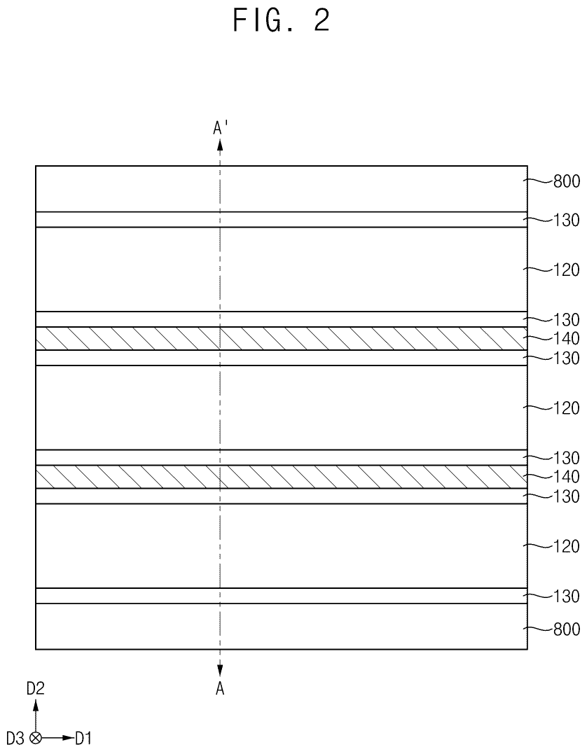

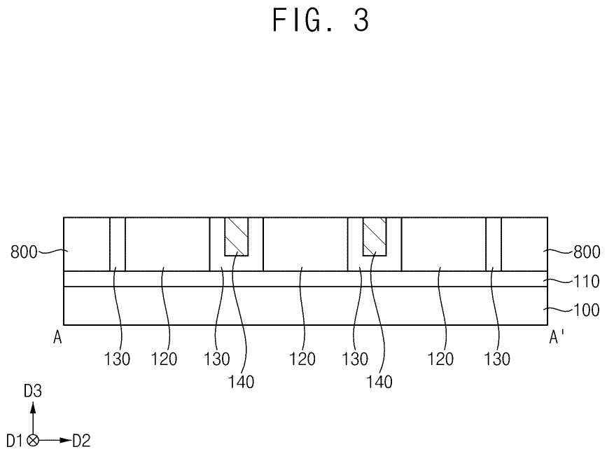

FIGS. 2 to 12 are plan views and cross-sectional views illustrating a method of manufacturing a semiconductor device in accordance with example embodiments. Specifically, FIGS. 2, 4 and 6 are the plan views, FIGS. 3, 5 and 7-12 are cross-sectional views taken along lines A-A′ of corresponding plan views, respectively.

Referring to FIGS. 2 and 3, a first substrate structure (which may be also referred to as first substrate) including a first sub-substrate 100, a buried oxide layer 110 and a second sub-substrate may be provided, and the second sub-substrate may be patterned to form a preliminary channel 120. The first and/or second sub-substrate may be bulk substrates.

In example embodiments, the preliminary channel 120 may extend in the first direction D1, and a plurality of preliminary channels 120 may be spaced apart from each other in the second direction D2. A first opening may be formed between ones of the preliminary channels 120 neighboring in the second direction D2 to expose an upper surface of the buried oxide layer 110.

A first gate insulation layer may be formed on the preliminary channel 120 and the buried oxide layer 110, an anisotropic etching process may be performed on the first gate insulation layer to remove a portion of the first gate insulation layer on an upper surface of the preliminary channel 120. Thus, a first gate insulation pattern 130 may be formed on a sidewall of the first opening and the upper surface of the buried oxide layer 110. In example embodiments, the first gate insulation pattern 130 may contact opposite sidewalls in the second direction D2 of respective ones of the preliminary channels 120 neighboring in the second direction D2 and an upper surface of a portion of the buried oxide layer 110 between the neighboring ones of the preliminary channels 120, and may extend in the first direction D1.

A first gate electrode layer may be formed on the preliminary channel 120 and the first gate insulation pattern 130, and a planarization process may be performed on the first gate electrode layer until upper surfaces of the preliminary channel 120 and the first gate insulation pattern 130 are exposed to form a first gate electrode 140. The planarization process may include, e.g., a chemical mechanical polishing (CMP) process and/or an etch back process.

In example embodiments, the first gate electrode may extend in the first direction D1, and a plurality of first gate electrodes 140 may be spaced apart from each other in the second direction D2.

The preliminary channel 120, the first gate insulation pattern 130 and the first gate electrode 140 may be partially removed to form a second opening exposing the upper surface of the buried oxide layer 110, and a first insulating interlayer 800 may be formed in the second opening.

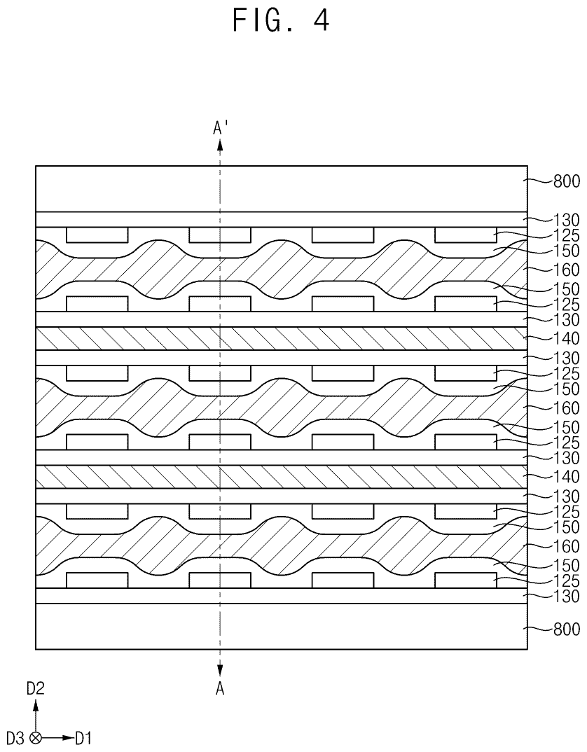

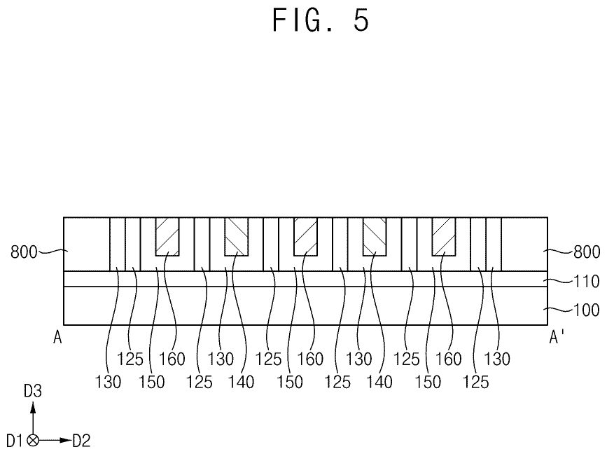

Referring to FIGS. 4 and 5, the preliminary channel 120 may be patterned to form a channel 125.

In example embodiments, a plurality of channels 125 may be spaced apart from each other in the first direction D1 on a sidewall in the second direction D2 of the first gate insulation pattern 130 extending in the first direction D1. A third opening may be formed between ones of the channels 125 that are disposed between ones of the first gate insulation patterns 130 neighboring in the second direction D2, and may expose the upper surface of the buried oxide layer 110.

A second gate insulation layer may be formed on the channel 125, the first gate insulation pattern 130, the first gate electrode 140 and the buried oxide layer 110, and a portion of the second gate insulation layer on upper surfaces of the channel 125, the first gate insulation pattern 130 and the first gate electrode 140 may be removed by, e.g., an anisotropic etching process to form a second gate insulation pattern 150.

In example embodiments, the second gate insulation pattern 150 may contact opposite sidewalls in the second direction D2 of ones of the first gate insulation patterns 130 neighboring in the second direction D2, opposite sidewalls in the second direction D2 of ones of the channels 125 neighboring in the second direction D2, an upper surface of a portion of the buried oxide layer 110 between the neighboring ones of the first gate insulation patterns 130 and an upper surface of a portion of the buried oxide layer 110 between the neighboring ones of the channels 125.

A second gate insulating interlayer layer may be formed on the channel 125, the first and second gate insulation patterns 130 and 150, the first gate electrode 140 and the first insulating interlayer 800, and a planarization process may be performed on the second gate electrode layer until upper surfaces of the channel 125, the first and second gate insulation patterns 130 and 150, the first gate electrode 140 and the first insulating interlayer 800 are exposed to form a second gate electrode 160. The planarization process may include a CMP process and/or an etch back process.

In example embodiments, the second gate electrode 160 may extend in the first direction D1, and a plurality of second gate electrodes 160 may be spaced apart from each other in the second direction D2. In example embodiments, the second gate electrode 160 may include an extension portion straightly extending in the first direction D1 and protrusion portions protruding from the extension portion in the second direction D2 and being spaced apart from each other in the first direction D1, in a plan view.

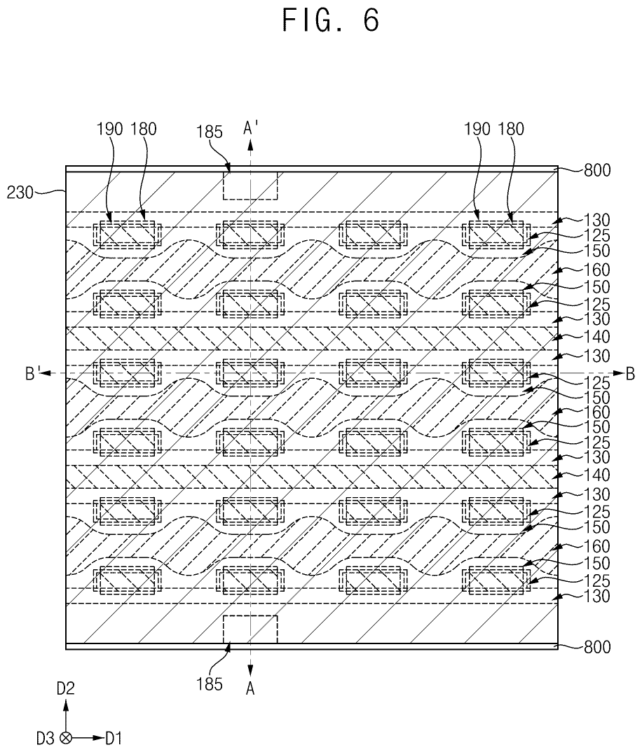

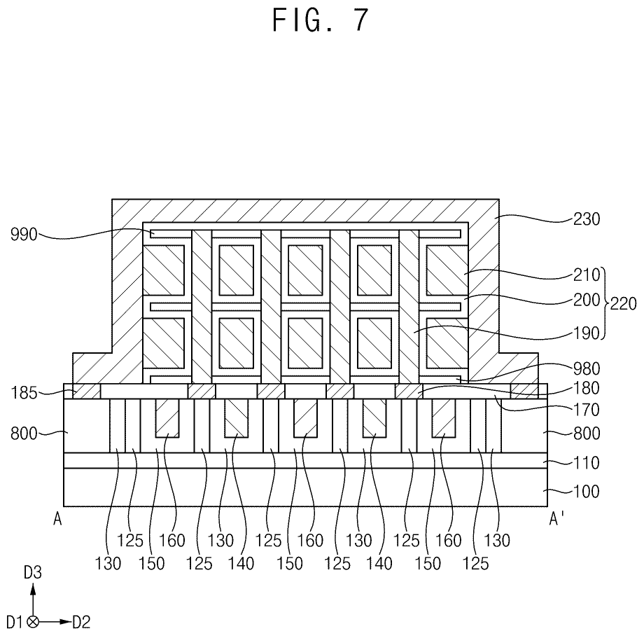

Referring to FIGS. 6 and 7, a second insulating interlayer 170 may be formed on the first and second gate electrodes 140 and 160, the channel 125, the first and second gate insulation patterns 130 and 150 and the first insulating interlayer 800, and first and second pads 180 and 185 may be formed through the second insulating interlayer 170.

In example embodiments, a plurality of first pads 180 may be spaced apart from each other in each of the first and second directions D1 and D2 to contact respective upper surfaces of the channels 125. The second pad 185 may extend through a portion of the second insulating interlayer 170 on the first insulating interlayer 800.

A capacitor 220 and a plate electrode 230 may be formed on the second insulating interlayer 170 and the first and second pads 180 and 185. The capacitor 220 and the plate electrode 230 may be formed by, e.g., following processes.

An etch stop layer 980 may be formed on the second insulating interlayer 170 and the first and second pads 180 and 185, and a mold layer and a support layer 990 may be alternately and repeatedly formed on the etch stop layer 980. The etch stop layer 980 may include an insulating nitride, e.g., silicon boronitride, the mold layer may include an oxide, e.g., silicon oxide, and the support layer 990 may include an insulating nitride, e.g., silicon nitride.

A fourth opening may be formed through the support layer 990, the mold layer and the etch stop layer 980 to expose upper surfaces of the first pads 180, a first capacitor electrode layer may be formed on the upper surfaces of the first pads 180, a sidewall of the fourth opening and an upper surface of an uppermost one of the support layers 990, and a planarization process may be performed on the first capacitor electrode layer until the upper surface of an uppermost one of the support layers 990 is exposed to form a first capacitor electrode 190 in the fourth opening.

The planarization process may include, e.g., a CMP process and/or an etch back process.

The support layer 990 and the mold layer may be partially removed to form a fifth opening exposing an upper surface of the etch stop layer 980, and the mold layer may be removed through the fifth opening.

In example embodiments, the mold layer may be removed by a wet etching process, and as the wet etching process is performed, a sixth opening may be formed to expose a sidewall of the first capacitor electrode 190 and the upper surface of the etch stop layer 980. However, the support layers 990 may remain on the sidewall of each of the first capacitor electrodes 190, and thus a surface of each of the support layers 990 may be exposed by the sixth opening.

A dielectric layer 200 may be formed on the sidewall of each of the first capacitor electrodes 190, the upper surface of the etch stop layer 980 and the surface of each of the support layers 990 exposed by the sixth opening, and a second capacitor electrode layer may be formed on the dielectric layer 200 to fill the sixth opening. The dielectric layer 200 and the second capacitor electrode layer may also be formed on an upper surface of the first capacitor electrode 190 and the upper surface of the uppermost one of the support layers 990.

For example, a wet etching process may be performed on the second capacitor electrode layer to form a second capacitor electrode 210 in the sixth opening. The first capacitor electrode 190, the dielectric layer 200 and the second capacitor electrode 210 may collectively form a capacitor 220.

A plate electrode 230 may be formed on an upper surface and a sidewall of the capacitor 220 and upper surfaces of the second insulating interlayer 170 and the second pad 185. The plate electrode 230 may contact the upper surface of the second pad 185.

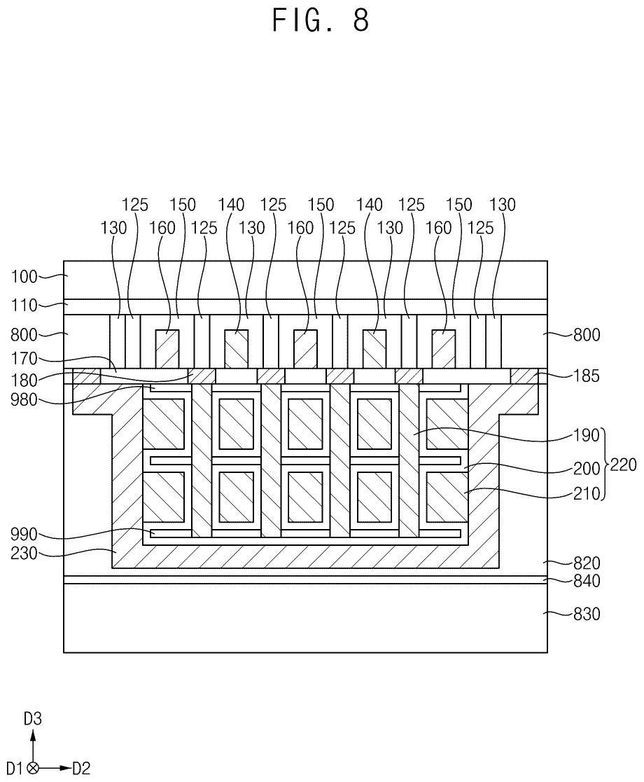

Referring to FIG. 8, a third insulating interlayer 820 may be formed on the plate electrode 230 and the second insulating interlayer 170, and a second substrate 830 may be bonded with an upper surface of the third insulating interlayer 820 with a first bonding layer 840 therebetween.

The second substrate 830 may include a semiconductor material, e.g., silicon, or an insulating material, e.g., glass. The first bonding layer 840 may include, e.g., silicon carbonitride, silicon oxide, etc.

A structure including the first substrate and the second substrate 830 may be flipped, reversing the top and bottom of the structure. Consequently, the subsequent explanation will be based on this reversed orientation.

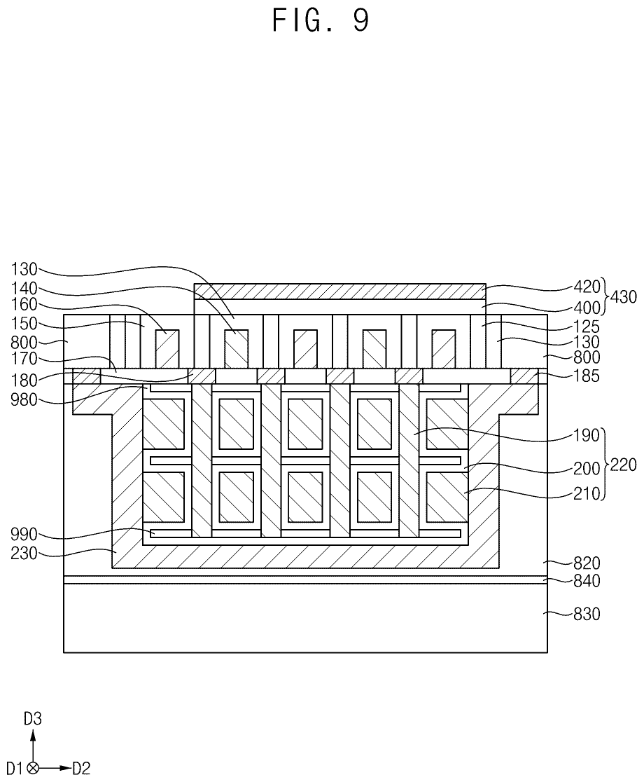

Referring to FIG. 9, the first sub-substrate 100 and the buried oxide layer 110 included in the first substrate structure may be removed by, e.g., a grinding process, and thus upper surfaces of the channel 125, the first and second gate insulation patterns 130 and 150 and the first insulating interlayer 800 may be exposed.

A bit line structure 430 may be formed on the upper surfaces of the channel 125, the first and second gate insulation patterns 130 and 150 and the first insulating interlayer 800. In example embodiments, the bit line structure 430 may extend in the second direction D2, and a plurality of bit line structures 430 may be spaced apart from each other in the first direction D1. Each of the bit line structures 430 may contact the upper surfaces of the channels 125 disposed in the second direction D2.

In an example embodiment, each of the bit line structures 430 may include first and second conductive patterns 400 and 420 stacked in the third direction D3, which may include, e.g., doped polysilicon and a metal, respectively.

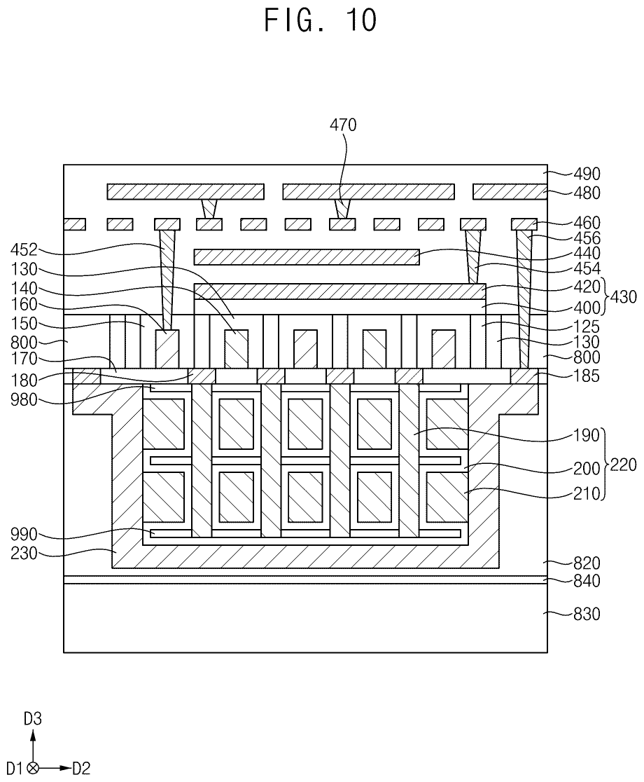

Referring to FIG. 10, first to third wirings 440, 460 and 480, first to third contact plugs 452, 454 and 456 and a first via 470 may be formed on the bit line structure 430, and a fourth insulating interlayer 490 may be formed on the channel 125, the first and second gate insulation patterns 130 and 150 and the first insulating interlayer 800 to cover the first to third wirings 440, 460 and 480, the first to third contact plugs 452, 454 and 456 and the first via 470.

Referring to FIG. 11, a third substrate structure 500 may be bonded with an upper surface of the fourth insulating interlayer 490 with a second bonding layer 530 therebetween.

The third substrate structure 500 may be doped with, e.g., p-type impurities, and may include first and second regions 510 and 520 having different impurity concentrations from each other. The second bonding layer 530 may include, e.g., silicon carbonitride, silicon oxide, etc.

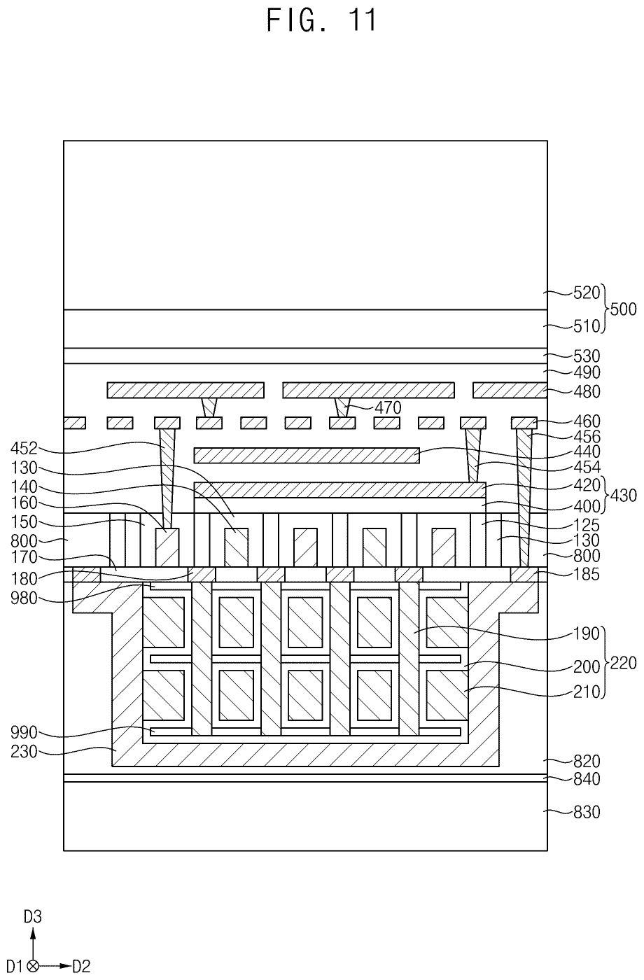

Referring to FIG. 12, a second region 520 of the third substrate structure 500 may be removed by, e.g., a grinding process to expose an upper surface of a first region 510 of the third substrate structure 500.

Hereinafter, the first region 510 of the third substrate structure 500 may be referred to as a third substrate 510.

An isolation pattern 540 may be formed at an upper portion of the third substrate 510, and a first insulation pattern 550 may be formed through the third substrate 510, the second bonding layer 530 and an upper portion of the fourth insulating interlayer 490 to contact an upper surface of the third wiring 480.

Referring to FIG. 1 again, a first impurity region 515 may be formed at an upper portion of the third substrate 510, a gate structure 630 may be formed on the third substrate 510, and second and third impurity regions 642 and 644 may be formed at upper portions of the third substrate 510 adjacent to the gate structure 630. Thus, a first transistor including the gate structure 630 and the second impurity regions 642 and a second transistor including the gate structure 630 and the third impurity regions 644 may be formed.

A fifth insulating interlayer 750 may be formed on the third substrate 510 to cover the first and second transistors, fourth and fifth contact plugs 652 and 654 extending through the fifth insulating interlayer 750 to contact upper surfaces of the second and third impurity regions 642 and 644, respectively, and a through via 655 extending through the fifth insulating interlayer 750 and the first insulation pattern 550 to contact an upper surface of the third wiring 480 may be formed.

A sixth contact plug 670, fourth to eighth wirings 660, 680, 720 and 740 and second to fourth vias 690, 710 and 730 may be formed on the fifth insulating interlayer 750, and a sixth insulating interlayer 760 may be formed on the fifth insulating interlayer 750 to cover the fourth to eighth wirings 660, 680, 720 and 740 and the second to fourth vias 690, 710 and 730 so that the fabrication of the semiconductor device may be completed.

As illustrated above, the memory cells may be formed on the first substrate structure, the first substrate structure may be bonded to the second substrate 830 with the first bonding layer 840 therebetween, the structure including the first substrate structure, the memory cells and the second substrate 830 may be flipped, the third substrate structure 500 may be bonded to the structure with the second bonding layer 530 therebetween, the second region 520 of the third substrate structure 500 may be removed, and the peripheral circuit patterns including the first and second transistors may be formed on the first region 510 of the third substrate structure 500.

If the first and second transistors are formed on the first region 510 of the third substrate structure 500 are formed, the third substrate structure 500 is bonded to a handling substrate with a third bonding layer therebetween, a structure including the third substrate structure 500 and the handling substrate is flipped, the second region 520 of the third substrate 500 is removed by a grinding process, the structure is flipped and is bonded to the second substrate 830 having the memory cells thereon, the third bonding layer and the handling substrate are removed, and the peripheral circuit patterns are formed, three bonding processes are needed in the manufacturing of the semiconductor device, which may increase the cost for manufacturing the semiconductor device.

However, in example embodiments of the present invention, the third substrate structure 500 is bonded to the memory cells on the second substrate 830 with the second bonding layer 530 therebetween, the second region 520 of the third substrate structure 500 is removed, and the peripheral circuit patterns may be formed on the first region 510 of the third substrate structure 500. Thus, two bonding processes may be sufficient in the manufacturing process of the semiconductor device, thereby decreasing the cost for manufacturing the semiconductor device.

The second bonding layer 530 and the third substrate structure 500 may be bonded to the upper surface of the fourth insulating interlayer 490 covering the memory cells, and no grinding process may be performed on a lower surface of the third substrate structure 500 contacting the second bonding layer 530. Thus, the lower surface of the third substrate structure 500 may be substantially flat.

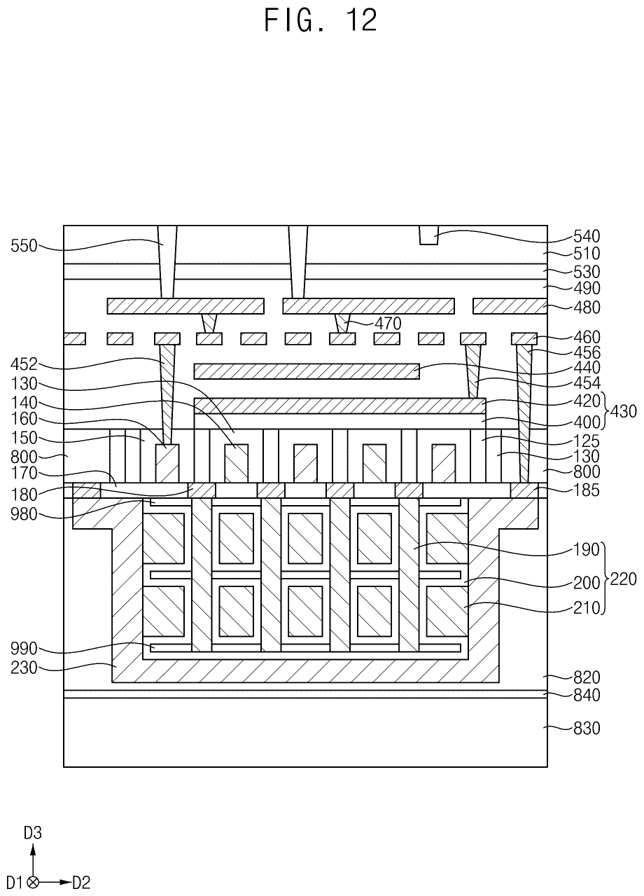

FIG. 13 is a cross-sectional view illustrating a semiconductor device in accordance with example embodiments, which may correspond to FIG. 1. This semiconductor device may be substantially the same as or similar to that of FIG. 1 except for some elements, and thus repeated explanations are omitted herein.

Referring to FIG. 13, the through via 655 may extend through a second insulation pattern 555, which may extend through the fifth insulating interlayer 750, the third substrate 510, the second bonding layer 530 and the upper portion of the fourth insulating interlayer 490, to contact the upper surface of the third wiring 480, and thus an entire portion of a sidewall of the through via 655 may contact the second insulation pattern 555.

The first insulation pattern 550 of FIG. 1 extends through the third substrate 510, the second bonding layer 530 and the upper portion of the fourth insulating interlayer 490, and upper and lower portions of the through via 655 contact the fifth insulating interlayer 750 and the first insulation pattern 550, respectively, while the through via 655 of FIG. 13 may not contact the fifth insulating interlayer 750 but may contact only the second insulation pattern 555.

The second insulation pattern 555 may include an oxide, e.g., silicon oxide.

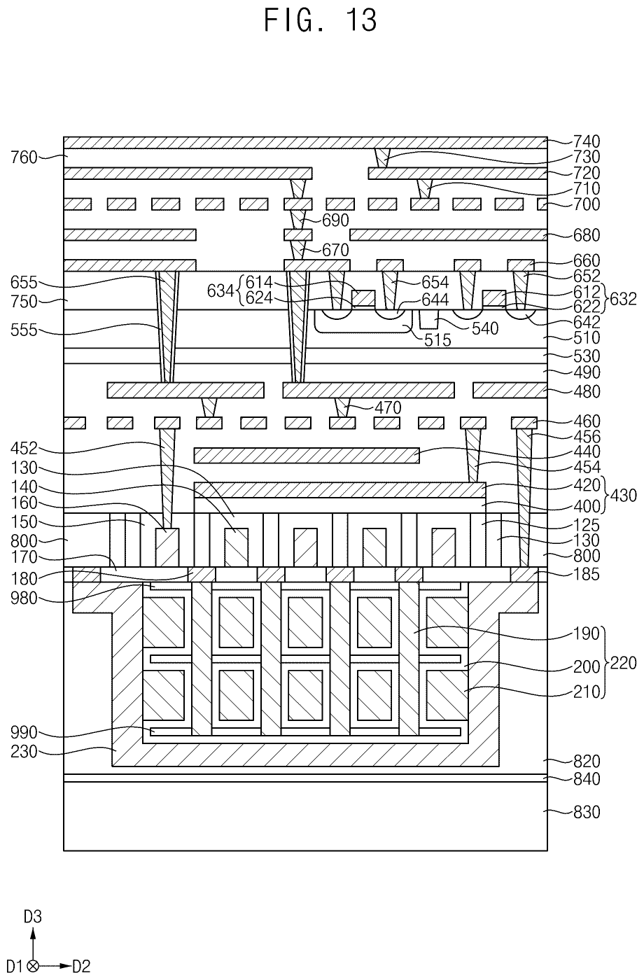

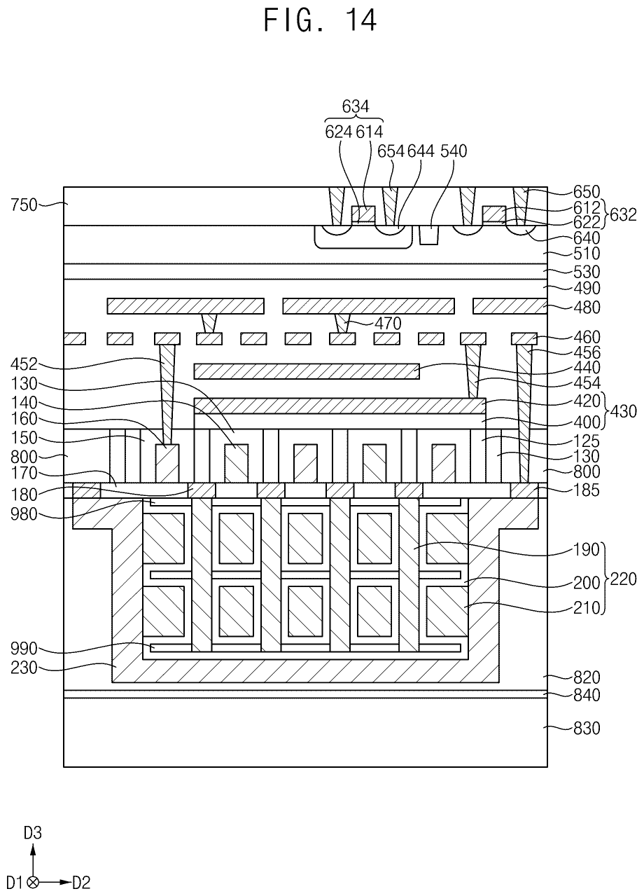

FIGS. 14 and 15 are cross-sectional views illustrating a method of manufacturing a semiconductor device, particularly the semiconductor device of FIG. 13. This method may include processes substantially the same as or similar to those illustrated with respect to FIGS. 2 to 12 and FIG. 1, and thus repeated explanations are omitted herein.

Referring to FIG. 14, processes substantially the same as or similar to those illustrated with respect to FIGS. 2 to 11 may be performed, the second region 520 of the third substrate structure 500 may be removed by, e.g., a grinding process to expose the upper surface of the first region 510 of the third substrate structure 500 that is, the upper surface of the third substrate 500.

The isolation pattern 540 may be formed at the upper portion of the third substrate 510, the first impurity region 515 and the first and second transistors may be formed, the fifth insulating interlayer 750 may be formed on the third substrate 510 to cover the first and second transistors, and the fourth and fifth contact plugs 652 and 654 may be formed through the fifth insulating interlayer 750 to contact the upper surfaces of the second and third impurity regions 642 and 644, respectively.

Referring to FIG. 15, a seventh opening 557 may be formed through the fifth insulating interlayer 750, the third substrate 510, the second bonding layer 530 and the upper portion of the fourth insulating interlayer 490 to expose the upper surface of the third wiring 480, and a second insulation pattern 555 may be formed on a sidewall of the seventh opening 557.

In example embodiments, the second insulation pattern 555 may be formed by forming a second insulation layer on the upper surface of the third wiring 480 exposed by the seventh opening 557, the sidewall of the seventh opening 557, and an upper surface of the fifth insulating interlayer 750, and performing an anisotropic etching process on the second insulation layer.

Referring to FIG. 13 again, the through via 655 may be formed in the seventh opening 557, the sixth contact plug 670, the fourth to eighth wirings 660, 680, 700, 720 and 740 and the second to fourth vias 690, 710 and 730 may be formed on the fifth insulating interlayer 750 and the through via 655, and the sixth insulating interlayer 760 may be formed to cover the sixth contact plug 670, the fourth to eighth wirings 660, 680, 700, 720 and 740 and the second to fourth vias 690, 710 and 730, so that the fabrication of the semiconductor device may be completed.

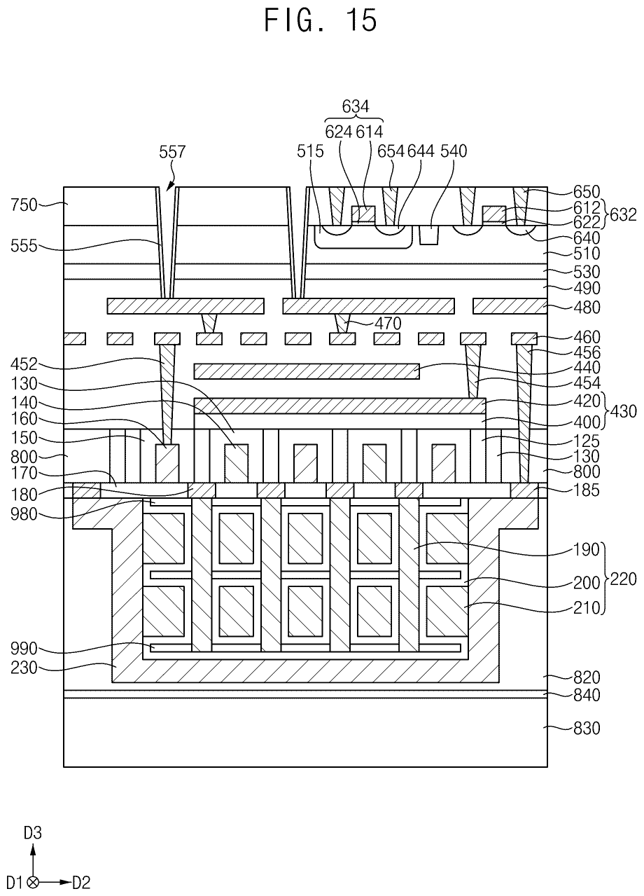

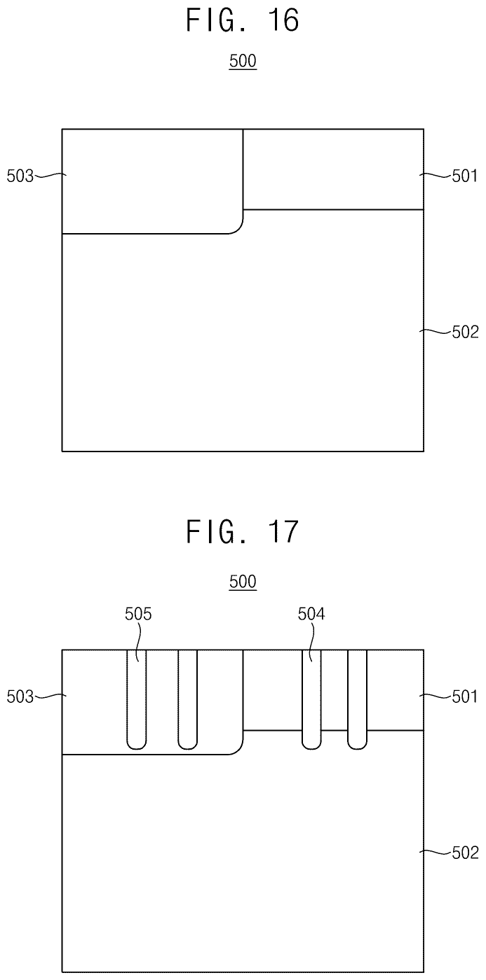

FIGS. 16 to 20 are cross-sectional views illustrating a method of manufacturing a semiconductor device in accordance with example embodiments, which are drawings about the third substrate structure 500.

This method may include processes substantially the same as or similar to those illustrated with respect to FIGS. 2 to 12 and FIG. 1, and thus repeated explanations are omitted herein.

Referring to FIG. 16, processes substantially the same as or similar to those illustrated with respect to FIGS. 2 to 10 may be performed, and the third substrate structure (also referred to as third substrate) 500 may be provided.

In an example embodiment, p-type impurities may be doped into an upper portion of the third substrate structure 500 by a first ion implantation process to form a first p-type impurity region 501. A lower portion of the third substrate structure 500 may remain as an undoped region 502. However, the inventive concept is not limited thereto, and alternatively, the p-type impurities may also be doped into the lower portion of the third substrate structure 500 so that the first p-type impurity region 501 may be formed in an entire portion of the third substrate structure 500.

N-type impurities may be doped into the upper portion of the third substrate structure 500 by a second ion implantation process to form a first n-type impurity region 503. In example embodiments, the first n-type impurity region 503 may be formed adjacent to the first p-type impurity region 501 and at a portion of the undoped region 502 adjacent to the first n-type impurity region 503.

Referring to FIG. 17, n-type impurities may be doped into the upper portion of the third substrate structure 500 by a third ion implantation process to form a second n-type impurity region 504, and p-type impurities may be doped into the upper portion of the third substrate structure 500 by a fourth ion implantation process to form a second p-type impurity region 505.

In example embodiments, the second n-type impurity region 504 may be formed at a portion of the first p-type impurity region 501 and a portion of the undoped region 502 adjacent to the first p-type impurity region 501, and the second p-type impurity region 505 may be formed at a portion of the first n-type impurity region 503.

In an example embodiment, a lower surface of the second n-type impurity region 504 and a lower surface of the second p-type impurity region 505 may be substantially coplanar with each other, however, the inventive concept is not limited thereto.

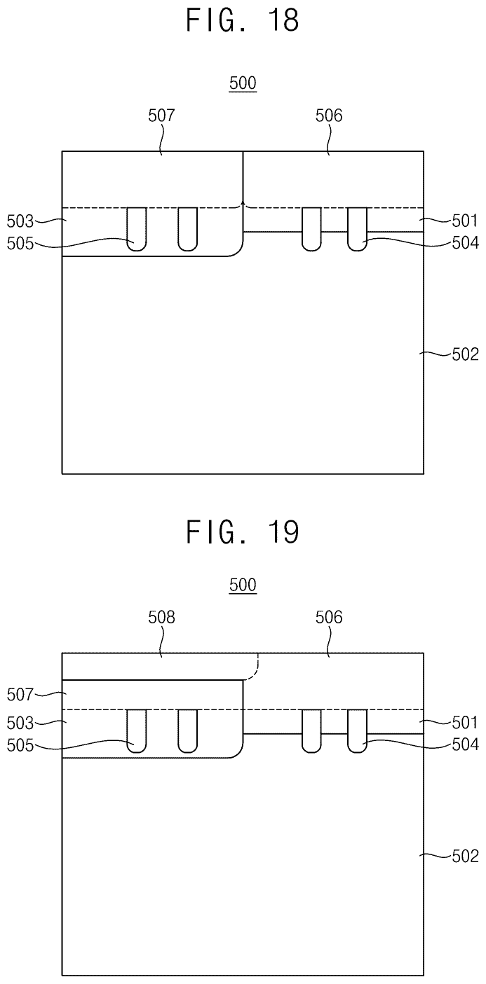

Referring to FIG. 18, p-type impurities may be doped into the upper portion of the third substrate structure 500 by a fifth ion implantation process to form a third p-type impurity region 506, and n-type impurities may be doped into the upper portion of the third substrate structure 500 by a sixth ion implantation process to form a third n-type impurity region 507.

In example embodiments, the third p-type impurity region 506 may be formed at an upper portion of the first p-type impurity region 501 and an upper portion of the second n-type impurity region 504, and the third n-type impurity region 507 may be formed at an upper portion of the first n-type impurity region 503 and an upper portion of the second p-type impurity region 505.

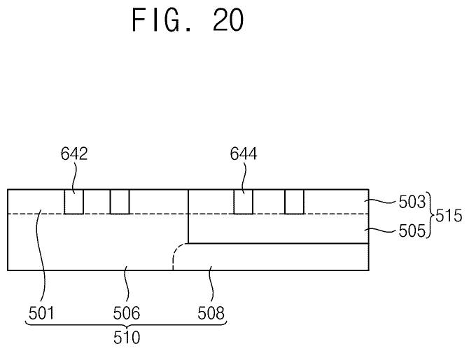

Referring to FIG. 19, p-type impurities may be doped into the upper portion of the third substrate structure 500 by a seventh ion implantation process to form a fourth p-type impurity region 508.

In example embodiments, the fourth p-type impurity region 508 may be formed at an upper portion of the third n-type impurity region 507, and may contact the third p-type impurity region 506.

Referring to FIG. 20, similarly to the processes illustrated with reference to FIG. 11, the third substrate structure 500 may be bonded to the upper surface of the fourth insulating interlayer 490 with the second bonding layer 530 therebetween.

The second bonding layer 530 may be formed on a surface of the third substrate structure 500 under which the third and fourth impurity regions 506 and 508 are formed, and the third substrate structure 500 may be flipped to be bonded to the upper surface of the fourth insulating interlayer 490.

Similarly to the processes illustrated with reference to FIG. 12, an upper portion of the third substrate structure 500 may be removed by, e.g., a grinding process, and the undoped region 502 and upper portions of the first and second n-type impurity regions 503 and 504 and the second p-type impurity region 505 of the third substrate structure 500 may be removed.

Thus, the first, third and fourth p-type impurity regions 501, 506 and 508, the first and third n-type impurity regions 503 and 507, the second n-type impurity region 504 and the second p-type impurity region 505 may form the first region 510, the first impurity region 515, the second impurity region 642 and the third impurity region 644, respectively, shown in FIG. 1.

Processes substantially the same as or similar to those illustrated with respect to FIGS. 12 to 14 and FIG. 1 may be performed to complete the fabrication of the semiconductor device.

As illustrated above, before bonding the third substrate structure 500 to the upper surface of the fourth insulating interlayer 490 on the memory cells using the second bonding layer 530, ion implantation processes may be performed to form the first to third impurity regions 515, 642 and 644 in the third substrate structure 500.

If after bonding the third substrate structure 500 to the upper surface of the fourth insulating interlayer 490 on the memory cells, the ion implantation processes are performed to form the first to third impurity regions 515, 642 and 644, the ion implantation processes are need performing at a lower temperature so as not to deteriorate the characteristics of the memory cells, which may increase the difficulty of the ion implantation processes.

However, in example embodiments of the present invention, the ion implantation processes may be performed before bonding the third substrate structure to the memory cells, so that the difficulty of the ion implantation processes may decrease and the electrical characteristics of the first to third impurity regions 515, 642 and 644 may be enhanced.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims.

In a case where the claims are interpreted as including a means-plus-function clause, the means-plus-function clause is intended to cover the structures described herein as performing the recited function and not only structural equivalents (in the context of literal infringement of the means-plus-function claim) but also equivalent structures (under the doctrine of equivalents). Therefore, it is to be understood that the foregoing is illustrative of various example embodiments and is not to be construed as limiting the invention to the specific example embodiments disclosed, and that modifications to the disclosed example embodiments, as well as other example embodiments, are intended to be included within the scope of the appended claims.

What is claimed is:

1. A semiconductor device comprising:
a capacitor on a first substrate;
a channel on and electrically connected to the capacitor, the channel extending in a vertical direction perpendicular to an upper surface of the first substrate;
a first gate electrode at a side of the channel, the first gate electrode spaced apart from the channel in a first direction parallel to the upper surface of the first substrate, the first gate electrode extending in a second direction parallel to the upper surface of the first substrate and crossing the first direction;
a bit line in contact with and electrically connected to an end of the channel in the vertical direction, the bit line extending in the first direction;
a first wiring on the bit line;
a first insulating interlayer on the bit line and the first wiring;
a bonding layer bonded to an upper surface of the first insulating interlayer;
a second substrate bonded to an upper surface of the bonding layer;
a transistor at least a portion of which is on the second substrate;
a second insulating interlayer on the second substrate and covering the transistor;
a second wiring on the second insulating interlayer;
an insulation pattern extending through the second substrate, the bonding layer and an upper portion of the first insulating interlayer, the insulation pattern contacting an upper surface of the first wiring; and
a through via extending through the second insulating interlayer and the insulation pattern, the through via contacting the first and second wirings.

2. The semiconductor device according to claim 1, wherein the through via contacts the second insulating interlayer and the insulation pattern.

3. The semiconductor device according to claim 1, wherein the insulation pattern extends through the second insulating interlayer, and wherein the through via contacts the insulation pattern.

4. The semiconductor device according to claim 1, further comprising a plate electrode surrounding a lower surface and a sidewall of the capacitor.

5. The semiconductor device according to claim 4, wherein the plate electrode includes a metal or doped silicon-germanium.

6. The semiconductor device according to claim 1, further comprising a first gate insulation pattern covering a sidewall and an upper surface of the first gate electrode.

7. The semiconductor device according to claim 1, further comprising a second gate electrode extending in the second direction, the second gate electrode being spaced apart from the first gate electrode in the first direction.

8. The semiconductor device according to claim 7, further comprising a second gate insulation pattern covering a sidewall and an upper surface of the second gate electrode.

9. The semiconductor device according to claim 7, wherein the channel is disposed between the first and second gate electrodes.

10. The semiconductor device according to claim 1, wherein a lower surface of the second substrate bonded to the upper surface of the bonding layer, and
the lower surface of the second substrate is flat.

11. A semiconductor device comprising:
a capacitor on a first substrate;
a plate electrode covering a lower surface and a sidewall of the capacitor;
a channel on and electrically connected to the capacitor, the channel extending in a vertical direction perpendicular to an upper surface of the first substrate;
a first gate electrode at a side of the channel, wherein the side of the channel faces the first gate electrode in a first direction, the first gate electrode extends in a second direction, the first and second directions are parallel to the upper surface of the first substrate, and the second direction crosses the first direction;
a bit line in contact with and electrically connected to an end of the channel in the vertical direction, the bit line extending in the first direction;
a first wiring on the bit line;
a first insulating interlayer covering the bit line and the first wiring;
a bonding layer bonded to an upper surface of the first insulating interlayer;
a second substrate bonded to an upper surface of the bonding layer;
a transistor at least a portion of which is on the second substrate;
a second wiring on the second substrate; and
an insulation pattern extending through the second substrate, the bonding layer and an upper portion of the first insulating interlayer, the insulation pattern contacting an upper surface of the first wiring.

12. The semiconductor device according to claim 11, further comprising a through via extending through the insulation pattern and contacting the first and second wirings.

13. The semiconductor device according to claim 12, wherein an upper portion of the through via does not contact the insulation pattern.

14. The semiconductor device according to claim 12, further comprising a second insulating interlayer on the second substrate and covering the transistor,
wherein the through via extends through the second insulating interlayer, an upper portion of the through via contacts the second insulating interlayer, and a lower portion of the through via contacts the insulation pattern.

15. The semiconductor device according to claim 11, further comprising a second gate electrode extending in the second direction and being spaced apart from the first gate electrode in the first direction.

16. A semiconductor device comprising:
a capacitor on a first substrate;
a plate electrode covering a lower surface and a sidewall of the capacitor;
a channel on and electrically connected to the capacitor, the channel extending in a vertical direction perpendicular to an upper surface of the first substrate;
a word line at a first side of the channel, the word line spaced apart from the channel in a first direction parallel to the upper surface of the first substrate, the word line extending in a second direction parallel to the upper surface of the first substrate and crossing the first direction;
a first gate insulation pattern covering an upper surface of the word line and a pair of sidewalls of the word line, wherein the pair of sidewalls of the word line face away from each other in the first direction;
a back gate electrode at a second side of the channel, the back gate electrode spaced apart from the channel in the first direction and extending in the second direction;
a second gate insulation pattern covering an upper surface of the back gate electrode and a pair of sidewalls of the back gate electrode, wherein the pair of sidewalls of the back gate electrode face away from each other in the first direction;
a bit line in contact with and electrically connected to an end of the channel in the vertical direction, the bit line extending in the first direction;
a first wiring on the bit line;
a first insulating interlayer covering the bit line and the first wiring;
a bonding layer bonded to an upper surface of the first insulating interlayer;
a second substrate bonded to an upper surface of the bonding layer;
a transistor at least a portion of which is on the second substrate;
a second insulating interlayer on the second substrate and covering the transistor;
a second wiring on the second insulating interlayer;
an insulation pattern extending through the second substrate, the bonding layer and an upper portion of the first insulating interlayer, the insulation pattern contacting an upper surface of the first wiring; and
a through via extending through the second insulating interlayer and the insulation pattern and contacting the first and second wirings.

17. The semiconductor device according to claim 16, wherein the through via contacts the second insulating interlayer and the insulation pattern.

18. The semiconductor device according to claim 16, wherein the insulation pattern extends through the second insulating interlayer, and
wherein the through via contacts the insulation pattern.

19. The semiconductor device according to claim 16, wherein the word line and the back gate electrode are alternately disposed in the first direction.

20. The semiconductor device according to claim 16, wherein a lower surface of the second substrate bonded to the upper surface of the bonding layer, and the lower surface of the second substrate is flat.
